(19) United States
(12) Patent Application Publication
(10) Pub. No.: US 2025/0331193 A1
(43) Pub. Date: Oct. 23, 2025

(54) SEMICONDUCTOR DEVICES AND FABRICATING METHODS THEREOF

(71) Applicant: YANGTZE MEMORY TECHNOLOGIES CO., LTD., Wuhan (CN)

(72) Inventors: Dongxue Zhao, Wuhan (CN); Zhiliang Xia, Wuhan (CN); Changzhi Sun, Wuhan (CN); Tao Yang, Wuhan (CN); Yuxuan Fang, Wuhan (CN); Lei Liu, Wuhan (CN)

(21) Appl. No.: 18/745,354

(22) Filed: Jun. 17, 2024

Related U.S. Application Data
(63) Continuation of application No. PCT/CN2024/089031, filed on Apr. 22, 2024.

(51) Int. Cl. H10B 53/20; H10B 53/30; H10B 53/40

(52) U.S. Cl. CPC H10B 53/20; H10B 53/30; H10B 53/40

(57) ABSTRACT

Semiconductor devices and fabricating methods thereof are provided. A disclosed semiconductor device comprises a first semiconductor stack and a second semiconductor stack being vertically stacked on the first semiconductor stack. The first semiconductor stack comprises a first transistor layer comprising an array of first vertical transistors, each first vertical transistor comprising a first vertical channel structure comprising a first material, and a first storage layer vertically stacked on the first transistor layer and comprising an array of first capacitors. The second semiconductor stack comprises a second transistor layer comprising an array of second vertical transistors, each second vertical transistor comprising a second vertical channel structure comprising a second material different from the first material, and a second storage layer being vertically stacked on the second transistor layer and comprising an array of second capacitors.

### CROSS-REFERENCE TO RELATED APPLICATIONS

This application is a continuation of International Application No. PCT/CN2024/089031, filed on Apr. 22, 2024, which is hereby incorporated by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In some aspects of the present disclosure, a semiconductor device, comprising: a first semiconductor stack comprising: a first transistor layer comprising an array of first vertical transistors, each first vertical transistor comprising a first vertical channel structure comprising a first material, and a first storage layer vertically stacked on the first transistor layer and comprising an array of first capacitors each coupled with a corresponding one of the array of the first vertical transistors; and a second semiconductor stack being vertically stacked on the first semiconductor stack, and comprising: a second transistor layer comprising an array of second vertical transistors, each second vertical transistor comprising a second vertical channel structure comprising a second material different from the first material, and a second storage layer being vertically stacked on the second transistor layer and comprising an array of second capacitors each coupled with a corresponding one of the array of the second vertical transistors.

In some implementations, the first material is monocrystalline silicon; and the second material is polycrystalline silicon or silicon-germanium.

In some implementations, the first material is monocrystalline silicon; and the second material is a metal oxide semiconductor material.

In some implementations, each first vertical transistor further comprises a first gate structure at a lateral side of the first vertical channel structure; and each second vertical transistor further comprises a second gate structure laterally surrounding the second vertical channel structure.

In some implementations, each first vertical transistor further comprises a first gate structure located at a first number of sides of the first vertical channel structure; each second vertical transistor further comprises a second gate structure located at a second number of sides of the second vertical channel structure; and the first number is different from the second number.

In some implementations, each first capacitor comprises a high-K dielectric material between two conductive layers; each second capacitor comprises a ferroelectric material between two conductive layers; and the second storage layer comprises more than one layer of second capacitors.

In some implementations, the semiconductor device further comprises: a peripheral circuit layer comprising peripheral circuits and being vertically stacked with the first semiconductor stack and the second semiconductor stack; a first bit line interconnection structure coupled between the peripheral circuits and first bit lines in the first semiconductor stack; and a second bit line interconnection structure extending through the first semiconductor stack and being coupled between the peripheral circuits and second bit lines in the second semiconductor stack.

In some implementations, the semiconductor device further comprises: the second transistor layer is located between the first storage layer and the second storage layer; and the semiconductor device further comprises: a first capacitor interconnection structure coupled between the peripheral circuits and a first common electrode of the first capacitors, and a second capacitor interconnection structure extending through the first semiconductor stack and being coupled between the peripheral circuits and a second common electrode of the second capacitors.

In some implementations, the first storage layer and the second storage layer are located between the first transistor layer and the second transistor layer; the array of first capacitors and the array of second capacitors share a common electrode; and the semiconductor device further comprises a common capacitor interconnection structure extending in the first semiconductor stack and being coupled between the peripheral circuits and the common electrode.

In some implementations, the semiconductor device further comprises: a third semiconductor stack being vertically stacked on the second semiconductor stack, and comprising: a third transistor layer comprising an array of third vertical transistors, and a third storage layer being vertically stacked on the third transistor layer and comprising an array of third capacitors each coupled with a corresponding one of the array of the third vertical transistors.

In some implementations, the second transistor layer and the third transistor layer are located between the second storage layer and the third storage layer; and the array of second vertical transistors and the array of third vertical transistors share a common bit line layer.

In some implementations, the third storage layer is located between the second transistor layer and the third transistor layer; and the semiconductor device further comprises a third bit line interconnection structure extending in the first, second, and third semiconductor stacks and being coupled between the peripheral circuits and third bit lines in the third semiconductor stack.

In another aspect of the present disclosure, a semiconductor device comprises: a first semiconductor stack comprising: a first transistor layer comprising an array of first vertical transistors, each first vertical transistor, and a first storage layer vertically stacked on the first transistor layer and comprising an array of first capacitors each comprising a high-K dielectric material between two conductive layers and being coupled with a corresponding one of the array of the first vertical transistors; and a second semiconductor stack being vertically stacked on the first semiconductor stack, and comprising: a second transistor layer comprising an array of second vertical transistors, and a second storage layer being vertically stacked on the second transistor layer and comprising an array of second capacitors each comprising a ferroelectric material between two conductive layers and being coupled with a corresponding one of the array of the second vertical transistors.

In some implementations, the second storage layer comprises more than one layer of second capacitors.

In some implementations, each first vertical transistor comprising a first vertical channel structure comprising a first material; and each second vertical transistor comprising a second vertical channel structure comprising a second material different from the first material.

In some implementations, the first material is monocrystalline silicon; and the second material is polycrystalline silicon or silicon-germanium.

In some implementations, the first material is monocrystalline silicon; and the second material is a metal oxide semiconductor material.

In some implementations, each first vertical transistor further comprises a first gate structure at a lateral side of the first vertical channel structure; and each second vertical transistor further comprises a second gate structure laterally surrounding the second vertical channel structure.

In some implementations, each first vertical transistor further comprises a first gate structure located at a first number of sides of the first vertical channel structure; each second vertical transistor further comprises a second gate structure located at a second number of sides of the second vertical channel structure; and the first number is different from the second number.

In some implementations, the semiconductor device further comprises: a peripheral circuit layer comprising peripheral circuits and being vertically stacked with the first semiconductor stack and the second semiconductor stack; a first bit line interconnection structure coupled between the peripheral circuits and first bit lines in the first semiconductor stack; and a second bit line interconnection structure extending through the first semiconductor stack and being coupled between the peripheral circuits and second bit lines in the second semiconductor stack.

In some implementations, the second transistor layer is located between the first storage layer and the second storage layer; and the semiconductor device further comprises: a first capacitor interconnection structure coupled between the peripheral circuits and a first common electrode of the first capacitors, and a second capacitor interconnection structure extending through the first semiconductor stack and being coupled between the peripheral circuits and a second common electrode of the second capacitors.

In some implementations, the first storage layer and the second storage layer are located between the first transistor layer and the second transistor layer; the array of first capacitors and the array of second capacitors share a common electrode; and the semiconductor device further comprises a common capacitor interconnection structure extending in the first semiconductor stack and being coupled between the peripheral circuits and the common electrode.

In some implementations, the semiconductor device further comprises: a third semiconductor stack being vertically stacked on the second semiconductor stack, and comprising: a third transistor layer comprising an array of third vertical transistors, and a third storage layer being vertically stacked on the third transistor layer and comprising an array of third capacitors each coupled with a corresponding one of the array of the third vertical transistors.

In some implementations, the second transistor layer and the third transistor layer are located between the second storage layer and the third storage layer; and the array of second vertical transistors and the array of third vertical transistors share a common bit line layer.

In some implementations, the third storage layer is located between the second transistor layer and the third transistor layer; and the semiconductor device further comprises a third bit line interconnection structure extending in the first, second, and third semiconductor stacks and being coupled between the peripheral circuits and third bit lines in the third semiconductor stack.

In another aspect of the present disclosure, a method for forming a semiconductor device comprises: forming a first semiconductor stack comprising: forming a first transistor layer comprising an array of first vertical transistors, comprising forming a first vertical channel structure for each first vertical transistor having a first material, and forming a first storage layer vertically stacked on the first transistor layer and comprising an array of first capacitors each coupled with a corresponding one of the array of the first vertical transistors; and forming a second semiconductor stack vertically stacked on the first semiconductor stack, and comprising: forming a second transistor layer comprising an array of second vertical transistors, comprising forming a second vertical channel structure for each second vertical transistor having a second material different from the first material, and forming a second storage layer being vertically stacked on the second transistor layer and comprising an array of second capacitors each coupled with a corresponding one of the array of the second vertical transistors.

In some implementations, the first material is monocrystalline silicon; and the second material is polycrystalline silicon or silicon-germanium.

In some implementations, the first material is monocrystalline silicon; and the second material is a metal oxide semiconductor material.

In some implementations, the metal oxide semiconductor material comprises one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In some implementations, forming the first transistor layer further comprises forming a first gate structure of each first vertical transistor at a first number of sides of the first vertical channel structure; forming the second transistor layer further comprises forming a second gate structure of each second vertical transistor at a second number of sides of the second vertical channel structure; and the first number is different from the second number.

In some implementations, forming the first storage layer comprises forming a high-K dielectric material between two conductive layers of the first capacitors; and forming the second storage layer comprises: forming a ferroelectric material between two conductive layers of the second capacitors, and forming more than one layer of second capacitors.

In some implementations, the method further comprises: forming a peripheral circuit layer comprising peripheral circuits and being vertically stacked with the first semiconductor stack and the second semiconductor stack; forming a first bit line interconnection structure coupled between the peripheral circuits and first bit lines in the first semiconductor stack; and forming a second bit line interconnection structure extending through the first semiconductor stack and being coupled between the peripheral circuits and second bit lines in the second semiconductor stack.

In some implementations, the second transistor layer is formed between the first storage layer and the second storage layer; and the method further comprises: forming a first capacitor interconnection structure coupled between the peripheral circuits and a first common electrode of the first capacitors, and forming a second capacitor interconnection structure extending through the first semiconductor stack and being coupled between the peripheral circuits and a second common electrode of the second capacitors.

In some implementations, the first storage layer and the second storage layer are formed between the first transistor layer and the second transistor layer; and the method further comprises: forming a common electrode shared by the array of first capacitors and the array of second capacitors, and forming a common capacitor interconnection structure extending in the first semiconductor stack and being coupled between the peripheral circuits and the common electrode.

In some implementations, the method further comprises: forming a third semiconductor stack vertically stacked on the second semiconductor stack, and comprising: forming a third transistor layer comprising an array of third vertical transistors, and forming a third storage layer vertically stacked on the third transistor layer and comprising an array of third capacitors each coupled with a corresponding one of the array of the third vertical transistors.

In some implementations, the second transistor layer and the third transistor layer are located between the second storage layer and the third storage layer; and the method further comprises forming a common bit line layer shared by the array of second vertical transistors and the array of third vertical transistors.

In some implementations, the third storage layer is located between the second transistor layer and the third transistor layer; and the method further comprises forming a third bit line interconnection structure extending in the first, second, and third semiconductor stacks and being coupled between the peripheral circuits and third bit lines in the third semiconductor stack.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a schematic circuit diagram of a semiconductor device including an array of memory cells according to some implementations of the present disclosure.

FIG. 2 illustrates a schematic side view of a cross-section of a semiconductor device, according to some implementations of the present disclosure.

FIG. 3 illustrates a schematic side view of a cross-section of a semiconductor device, according to some implementations of the present disclosure.

FIG. 4 illustrates a schematic side view of a cross-section of a semiconductor device, according to some implementations of the present disclosure.

FIG. 5 illustrates a schematic side view of a cross-section of a semiconductor device, according to some implementations of the present disclosure.

FIG. 6 illustrates a schematic side view of a cross-section of a semiconductor device, according to some implementations of the present disclosure.

FIG. 7 illustrates a block diagram of a system having a memory device, according to some implementations of the present disclosure.

FIG. 8 illustrates a flowchart of a fabricating method for forming a semiconductor device, according to some implementations of the present disclosure.

FIGS. 9A-9D each illustrates schematic views of the semiconductor device at a certain fabricating stage of the method shown in FIG. 8, according to various implementations of the present disclosure.

FIG. 10 illustrates a flowchart of a fabricating method for forming a semiconductor device, according to some implementations of the present disclosure.

FIGS. 11A-11E each illustrates schematic views of the semiconductor device at a certain fabricating stage of the method shown in FIG. 8, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some semiconductor devices, such as dynamic radon access memory (DRAM). In a one-transistor-one-capacitor (1T1C) DRAM structure or in a one-transistor-N-capacitor (1TNC) DRAM structure, the data is stored in the capacitors. Traditional DRAM devices adopt a 6F2 architecture, with logic circuits located laterally adjacent to the memory array, resulting in low density and challenges in miniaturization. On the other hand, vertical channel DRAM devices employ a 4F2 architecture, with logic circuits overlapping with the memory array in the vertical direction, thereby saving space and improving density. However, shrinking the size of storage units still presents difficulties, along with high manufacturing costs.

To address one or more of the aforementioned issues, the present disclosure introduces a multi-deck stacked DRAM architecture with logic circuits positioned stacked with the memory array in the vertical direction. Further, new materials are utilized in the channel structure of the transistors and in the capacitors to achieve diverse functionalities and increased memory density. For example, low-leakage materials, such as metal oxide semiconductor materials, are used as the channel of the select transistors to solve the leakage problem in the scaling process of DRAM. In another example, ferroelectric materials are used as the dielectric of the capacitors, making the DRAM device capable of non-volatile memory storage function. The corresponding fabricating processes of the multi-deck stacked DRAM architecture are described. By utilizing the new multi-deck stacked DRAM architecture and the corresponding new fabrication method, the disclosed semiconductor devices can achieve high memory density with a further reduced cell size.

Consistent with the scope of the present disclosure, according to some implementations of the present disclosure, the disclosed semiconductor devices include vertical transistors and vertical capacitors. Each vertical transistor includes a semiconductor layer extending in a vertical direction and a gate structure laterally beside the semiconductor layer. In some implementations, the word lines and bit lines connected to the vertical transistors are arranged along a first lateral direction and a second lateral direction, respectively. Each vertical capacitor includes vertically extended first electrode, second electrode, and capacitor dielectric between the first and second electrodes. By employing such an arrangement, memory area efficiency can be increased. Furthermore, the memory cell array and the peripheral circuits can be formed separately on different wafers, such that the fabricating processes of the memory cell array and the peripheral circuits do not affect each other, thereby further increasing the memory area efficiency.

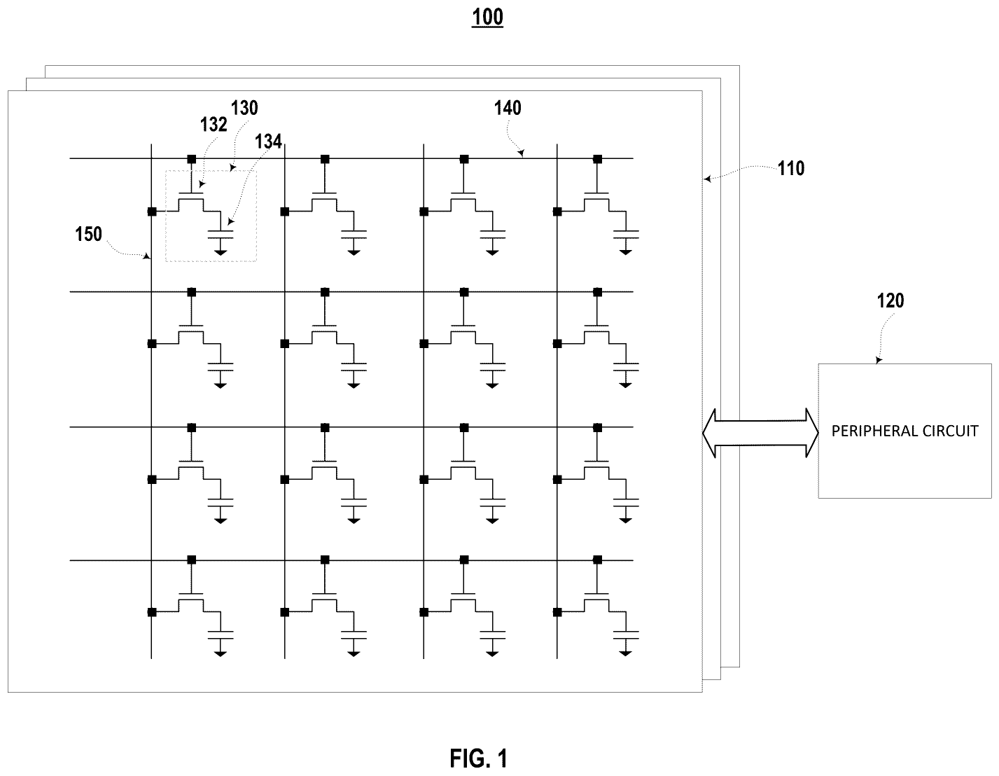

FIG. 1 illustrates a schematic diagram of a semiconductor device 100 including peripheral circuits and an array of memory cells each having a vertical transistor, according to some aspects of the present disclosure. Semiconductor device 100 can include a memory cell array 110 and peripheral circuits 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1, memory cells 130 can be arranged in a two-dimensional (2D) array having rows and columns. Peripheral circuits 120 can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuits 120 and memory cell array 110 for controlling the switch of vertical transistors 132 in memory cells 130 located in a row, as well as bit lines 150 coupling peripheral circuits 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the conventional planar transistors as the pass transistors of memory cells 130 to reduce the area occupied by the pass transistors, the coupling capacitance, as well as the interconnect routing complexity, as described below in detail. As shown in FIG. 1, in some implementations, different from planar transistors in which the active regions are formed in the substrates, vertical transistor 132 includes a semiconductor body extending vertically (in the z-direction) above the substrate (not shown). That is, the semiconductor body can extend above the top surface of the substrate to expose not only the top surface of the semiconductor body, but also one or more side surfaces thereof. As shown in FIG. 1, for example, the semiconductor body can have a cuboid shape to expose four sides thereof. It is understood that the semiconductor body may have any suitable shape, such as a polyhedron shape or a cylinder shape. That is, the cross-section of the semiconductor body in the plan view (e.g., in the x-y plane) can have a square shape, a rectangular shape (or a trapezoidal shape), a circular (or an oval shape), or any other suitable shapes. It is understood that in consistent with the scope of the present disclosure, for semiconductor bodies that have a circular or oval shape of their cross-sections in the plan view, the semiconductor bodies may still be considered to have multiple sides, such that the gate structures are coupled with more than one side of the semiconductor bodies.

In some implementations, the semiconductor bodies can be formed from the substrate (e.g., by etching or epitaxy) and thus, have the same semiconductor material (e.g., silicon crystalline silicon) as the substrate (e.g., a silicon substrate). In some implementations, the semiconductor bodies can include metal oxide and semiconductor materials, such as low-temperature polysilicon (LTPS) and indium gallium zinc oxide. Specifically, semiconductor bodies can include one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 1, vertical transistor 132 can also include a gate structure coupled with one or more lateral sides of semiconductor body. In other words, the active region of vertical transistor 132, i.e., the semiconductor body, can be at least partially surrounded by the gate structure. The ate structure can include a gate dielectric over one or more sides of the semiconductor body, e.g., coupled with four side surfaces of the semiconductor body as shown in FIG. 1. The gate structure can also include a gate electrode over and coupled with gate dielectric. The gate dielectric can include any suitable dielectric materials, such as silicon oxide, silicon nitride, silicon oxynitride, or high-k dielectrics. Gate electrodes can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1, vertical transistor 132 can further include a pair of a source and a drain (S/D, dope regions, a.k.a., source electrode and drain electrode) formed at the two ends of the semiconductor body in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the vertical direction (the z-direction). As a result, one or more channels (not shown) of vertical transistor 132 can be formed in the semiconductor body vertically between the source and drain when a gate voltage applied to the gate electrode of the gate structure is above the threshold voltage of vertical transistor 132.

In some implementations, the vertical transistors 132 can be single-gate transistors, in which the gate structure may be located at a single lateral side of the semiconductor body, for example, for the purpose of increasing the transistor and memory cell density. In some other implementations, vertical transistor 132 can be a multi-gate transistor. That is, the gate structure can be laterally located at more than one side of the semiconductor body to form more than one gate, such that more than one channel can be formed between the source and drain in operation. That is, different from the planar transistor that includes only a single planar gate (and resulting in a single planar channel), vertical transistor 132 shown in FIG. 1 can include multiple vertical gates on multiple lateral sides of the semiconductor body due to the semiconductor structure of semiconductor body and gate structure that locates on the multiple lateral sides of the semiconductor body. Compared with planar transistors, vertical transistor 132 shown in FIG. 1 can have a larger gate control area to achieve better channel control with a smaller subthreshold swing. During the off state, since the channel is fully depleted, the leakage current of vertical transistor 132 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

As shown in FIG. 1, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuits 120 can be coupled to memory cell array 110 through bit lines 150, word lines 140, and any other suitable metal wirings. As described above, peripheral circuits 120 can include any suitable circuits for facilitating the operations of memory cell array 110 by applying and sensing voltage signals and/or current signals through word lines 140 and bit lines 150 to and from each memory cell 130. Peripheral circuits 120 can include various types of peripheral circuits formed using CMOS technologies.

In some implementations, storage unit 134 can be pillar capacitors which are formed after forming the vertical transistors 132. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

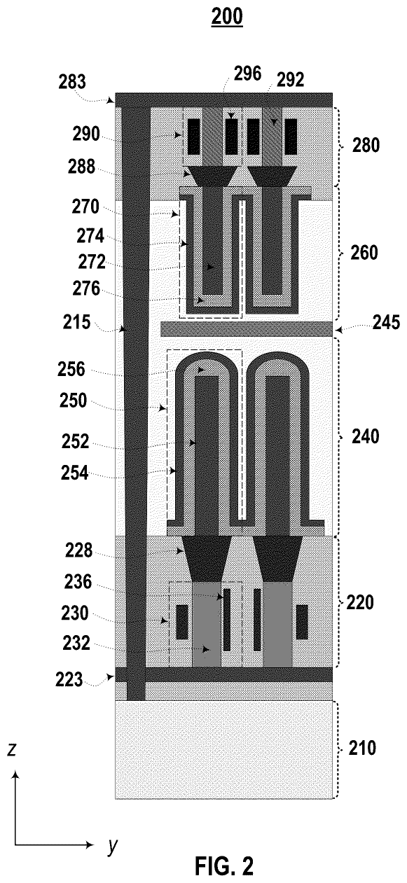

FIG. 2 illustrates a side view of a cross-section of a semiconductor device 200 including vertical transistors, according to some aspects of the present disclosure. It is understood that FIG. 2 is for illustrative purposes only and may not necessarily reflect the actual device structure (e.g., interconnections) in practice. Semiconductor device 200 can include a peripheral circuit layer 210 including the peripheral circuits of the semiconductor device 200. Semiconductor device 200 can also include a first semiconductor stack including a first transistor layer 220 and a first storage layer 240. Semiconductor device 200 can further include a second semiconductor stack including a second transistor layer 280 and a second storage layer 260.

In some implementations, semiconductor device 200 represents an example of a bonded chip. That is, the three stacks of semiconductor device 200, i.e., the peripheral circuit layer 210, the first semiconductor stack including the first transistor layer 220 and the first storage layer 240, and the second semiconductor stack including the second transistor layer 280 and the second storage layer 260, can be formed separately on different substrates and then joined to form a bonded chip. In some other implementations, semiconductor device 200 represents an example of a single chip. That is, the three stacks of semiconductor device 200, i.e., the peripheral circuit layer 210, the first semiconductor stack including the first transistor layer 220 and the first storage layer 240, and the second semiconductor stack including the second transistor layer 280 and the second storage layer 260, can be formed on a same substrate.

In some implementations, the peripheral circuit layer 210 can include a plurality of transistors (e.g., planar transistors and/or semiconductor transistors, not shown) formed on or in a substrate (not shown). Trench isolations (e.g., shallow trench isolations (STIs), not shown) and doped regions (e.g., wells, sources, and drains of transistors, not shown) can be formed on or in a substrate.

In some implementations, the first semiconductor stack includes a first transistor layer 220 in which memory cells are provided in the form of an array of DRAM cells. First transistor layer 220 can be an array of 1T1C cells each consisting of one transistor and one capacitor. In some implementations, the first transistor layer 220 includes an array of first transistors 230, and the first storage layer 240 includes an array of first capacitors 250. That is, each DRAM cell includes a first capacitor 250 and a first transistor 230 coupled with the first capacitor 250. First capacitors 250 can be formed on the first transistor layer 220 and include a first electrode 252, a second electrode 254, and a dielectric layer 256 formed between first electrode 252 and second electrode 254. First electrode 252 can be formed in a plurality of cell holes of an isolation layer. First capacitor 250 can be a vertical capacitor in which first and second electrodes 252 and 254, and dielectric layer 256 extend vertically (in the z-direction), and dielectric layer 256 can be sandwiched between first and second electrodes 252 and 254. In some implementations, the second electrodes 254 are connected with each other and function as a common electrode, while each first electrode 252 is coupled to a source of a respective first transistor 230 in the same DRAM cell through a source node contact (SNC) 228.

In some implementations, first electrodes 252 and/or the second electrode 254 can include conductive materials including, but not limited to, W, Co, Cu, Al, TiN, TaN, polysilicon, silicide, or any combination thereof. In some implementations, first electrodes 252 and/or the second electrode 254 include a multiple-layer structure, each layer of the multiple-layer structure comprising one of TiN, TaN, carbon, polysilicon, metal, metal compounds, and silicide. In some implementations, dielectric layer 256 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, the first capacitors 250 may be pillar capacitors and are formed after forming the first transistors 230. First capacitors 250 can have a relatively large height with or without using a mesh layer.

In some implementations, the first transistor layer 220 includes an array of first transistor 230 (e.g., a MOSFET) configured to switch a respective DRAM cell. In some implementations, each first transistor 230 includes a semiconductor body 232 (i.e., the active region in which multiple channels can form) extending vertically (in the z-direction), and a gate structure located at one or more lateral sides of semiconductor body 232. In some implementations, semiconductor body 232 can include any suitable semiconductor material, such as monocrystalline silicon, polycrystalline silicon, or silicon-germanium. In some other implementations, a leakage value of the semiconductor body 232 is lower than a pico-ampere, for example, semiconductor body 232 can include a metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc.

As shown in FIG. 2, in some implementations, semiconductor body 232 extends in a vertical direction (the z-direction), and includes a source and a drain disposed at the two ends (the upper end and lower end) of semiconductor body 232, respectively. Source and drain can be doped with N-type dopants (e.g., P or As) or P-type dopants (e.g., B or Ga) at a desired doping level. In some implementations, the source is coupled to first capacitor 250 through SNC 228, and the drain is coupled to bit line 223. In some implementations, SNC 228 may include a heavily doped polysilicon to form an Ohmic contact with source ends of first transistors 230 to decrease contact resistance. As shown in FIG. 2, the drains of first transistors 230 are coupled to bit line 223, which extends in the lateral direction (the y-direction).

In some implementations, the gate structure of first transistor 230 includes a gate dielectric and a gate electrode 236. In some implementations, the gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode 236 includes conductive materials including, but not limited to, W, Co, Cu, Al, TiN, TaN, polysilicon, silicide, or any combination thereof. In some implementations, the gate electrode 236 includes multiple conductive layers, such as a W layer over a TiN layer. In one example, the gate structure may be a “gate oxide/gate poly” gate in which the gate dielectric includes silicon oxide, and the gate electrode 236 includes doped polysilicon. In another example, the gate structure may be a high-k metal gate (HKMG) in which the gate dielectric includes a high-k dielectric, and the gate electrode 236 includes a metal.

As described above, the gate electrode 236 may be part of a word line 236 or extend in the word line direction (the x-direction) as a word line 236. Each word line 236 can extend in the word line direction (the x-direction), and be coupled to a row of DRAM cells. That is, bit line 223 and word line 236 can extend in two perpendicular lateral directions, and semiconductor body 232 of first transistor 230 can extend in the vertical direction perpendicular to the two lateral directions in which bit line 223 and word line 236 extend.

In some implementations, the second semiconductor stack includes a second transistor layer 280, in which memory cells are provided in the form of an array of DRAM cells. DRAM cell can be an array of 1T1C cells each consisting of one transistor and one capacitor. In some implementations, the second transistor layer 280 includes an array of second vertical transistors 290, and the second storage layer 260 includes an array of second capacitors 270. That is, each DRAM cell includes a second capacitor 270 and a second first transistor 230 coupled with the second capacitor 270.

As shown in FIG. 2, the second semiconductor stack can be formed on the first semiconductor stack in a face-to-face manner. That is, the first and second storage layers 240 and 260 are located between the first and second transistors layers 220 and 280 in the vertical direction. In some implementations, the first storage layers 240 and the second storage layer 260 are separated by a separation layer 245. In some implementations, the separation layer 245 includes a semiconductor layer, such as a heavily doped silicon layer.

In some implementations, the second capacitors 270 can include a first electrode 272, a second electrode 274, and a dielectric layer 276 formed between first electrode 272 and second electrode 274. First electrode 272 can be formed in a plurality of cell holes of an isolation layer. Second capacitor 270 can be a vertical capacitor in which first and second electrodes 272 and 274, and dielectric layer 276 extend vertically (in the z-direction), and dielectric layer 276 can be sandwiched between first and second electrodes 272 and 274. In some implementations, the second electrodes 274 are connected with each other and function as a common electrode, while each first electrode 272 is coupled to a source of a respective second transistor 290 in the same DRAM cell through a source node contact (SNC) 288.

In some implementations, second capacitors 270 can be cup capacitors, and may have a relatively large height without any mesh layer as second capacitors 270 are formed in cell holes of the isolation layer directly. Second capacitors 270 can keep stability during the fabrication process as no replacement of a sacrifice layer is needed to form second capacitors 270. In some implementations, first electrodes 272 and/or the second electrode 274 can include conductive materials including, but not limited to, W, Co, Cu, Al, TiN, TaN, polysilicon, silicide, or any combination thereof. In some implementations, first electrodes 272 and/or the second electrode 274 include a multiple-layer structure, each layer of the multiple-layer structure comprising one of TiN, TaN, carbon, polysilicon, metal, metal compounds, and silicide.

In some implementations, the second capacitors 270 are traditional capacitors, and the dielectric layer 276 includes dielectric materials, such as silicon oxide, silicon nitride, or high-k dielectrics including, but not limited to, Al₂O₃, HfO₂, Ta₂O₅, ZrO₂, TiO₂, or any combination thereof. In some other implementations, the second capacitors 270 are ferroelectric capacitors (FeCaps), and the dielectric layer 276 includes ferroelectric materials, such as lead zirconate titanate (PZT), barium titanate (BaTiO₃), strontium bismuth tantalate (SBT), lead magnesium niobate-lead titanate (PMN-PT), lithium niobate (LiNbO₃), etc. It is noted that, ferroelectric materials possess a spontaneous electric polarization that can be reversed by applying an external electric field. This property allows ferroelectric capacitors to retain their polarization state even after the applied voltage is removed, making them capable of non-volatile memory storage. Further, ferroelectric capacitors can achieve high-density data storage with low power consumption. In some implementations, the dielectric layer 256 of the first capacitors 250 and the dielectric layer 276 of the second capacitors 270 include different materials.

In some implementations, the second transistor layer 280 includes an array of second transistor 290 (e.g., a MOSFET) configured to switch a respective DRAM cell. In some implementations, each second transistor 290 includes a semiconductor body 292 (i.e., the active region in which multiple channels can form) extending vertically (in the z-direction), and a gate structure located at one or more lateral sides of semiconductor body 292. In some implementations, semiconductor body 292 can include any suitable semiconductor material, such as monocrystalline silicon, polycrystalline silicon, or silicon-germanium. In some other implementations, a leakage value of the semiconductor body 292 is lower than a pico-ampere. For example, semiconductor body 292 can include a metal oxide semiconductor material, such as InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, etc. In some implementations, the semiconductor body 232 of the first transistors 230 and the semiconductor body 292 of the second transistors 290 include different materials.

As shown in FIG. 2, in some implementations, semiconductor body 292 extends in a vertical direction (the z-direction), and includes a source and a drain disposed at the two ends (the upper end and lower end) of semiconductor body 292, respectively. Source and drain can be doped with N-type dopants (e.g., P or As) or P-type dopants (e.g., B or Ga) at a desired doping level. In some implementations, the source is coupled to second capacitor 270 through SNC 288, and the drain is coupled to bit line 283. In some implementations, SNC 288 may include heavily doped polysilicon to form an Ohmic contact with the source ends of second transistors 290 to decrease contact resistance. As shown in FIG. 2, the drains of second transistors 290 are coupled to bit line 283, which extends in the lateral direction (the y-direction). In some implementations, the bit lines 283 of the second transistors 290 can be coupled with the bit line 223 of the first transistors 230 via through contacts 215. Through contacts 215 can penetrate the first transistor layer 220, the first storage layer 240, the second storage layer 260, and the second transistor layer 280, to connect between the bit lines 283 of the second transistors 290 and the bit line 223 of the first transistors 230.

In some implementations, the gate structure of second transistor 290 includes a gate dielectric and a gate electrode 296. In some implementations, the gate dielectric includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, the gate electrode 296 includes conductive materials including, but not limited to, W, Co, Cu, Al, TiN, TaN, polysilicon, silicide, or any combination thereof. In some implementations, the gate electrode 296 includes multiple conductive layers, such as a W layer over a TiN layer. In one example, the gate structure may be a “gate oxide/gate poly” gate in which the gate dielectric includes silicon oxide, and the gate electrode 296 includes doped polysilicon. In another example, the gate structure may be a high-k metal gate (HKMG) in which the gate dielectric includes a high-k dielectric, and the gate electrode 296 includes a metal. In some implementations, the gate electrode 296 may be part of a word line 296 or extend in the word line direction (the x-direction) as a word line 296. Each word line 296 can extend in the word line direction (the x-direction), and be coupled to a row of DRAM cells.

In some implementations, the first transistors 230 and the second transistors 290 can have different types of gate structures. For example, the first transistors 230 can be single-gate transistors, while the second transistors 290 can be GAA transistors. That is, in each first vertical transistor 230, the first gate structure is located at a first number of lateral sides of the semiconductor body 232, while in each second vertical transistor 290, the second gate structure is located at a second number of lateral sides of the semiconductor body 292, and the first number is different from the second number.

In some implementations, semiconductor device 200 can further include any other suitable components that are not illustrated in FIG. 2. For example, in some implementations, semiconductor device 200 can further include one or more interconnect layers including interconnect structures to electrically connect word lines 236 and 296, bit lines 223 and 283, second electrodes 254 and 274, etc., to transfer electrical signals. In some implementations, the one or more interconnect layers can include lateral interconnect lines and vertical interconnect access (VIA) contacts. In some implementations, the one or more interconnect layers can include a first bit line interconnection structure coupled between the peripheral circuits and first bit lines in the first semiconductor stack, and a second bit line interconnection structure extending through the first semiconductor stack and being coupled between the peripheral circuits and second bit lines in the second semiconductor stack. In some implementations, the one or more interconnect layers can include a first capacitor interconnection structure coupled between the peripheral circuits and a first common electrode of the first capacitors, and a second capacitor interconnection structure extending through the first semiconductor stack and being coupled between the peripheral circuits and a second common electrode of the second capacitors.

In some implementations, the one or more interconnect layers can also include local interconnects, such as bit line contacts, word line contacts, and capacitor contacts. As used herein, the term “interconnects” can broadly include any suitable types of interconnects, such as middle-end-of-line (MEOL) interconnects and back-end-of-line (BEOL) interconnects. The one or more interconnect layers can further include one or more interlayer dielectric (ILD) layers (also known as “intermetal dielectric (IMD) layers”) in which the interconnect lines and via contacts can form. That is, the one or more interconnect layers can include interconnect lines and via contacts in multiple ILD layers. The interconnects in the one or more interconnect layers can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

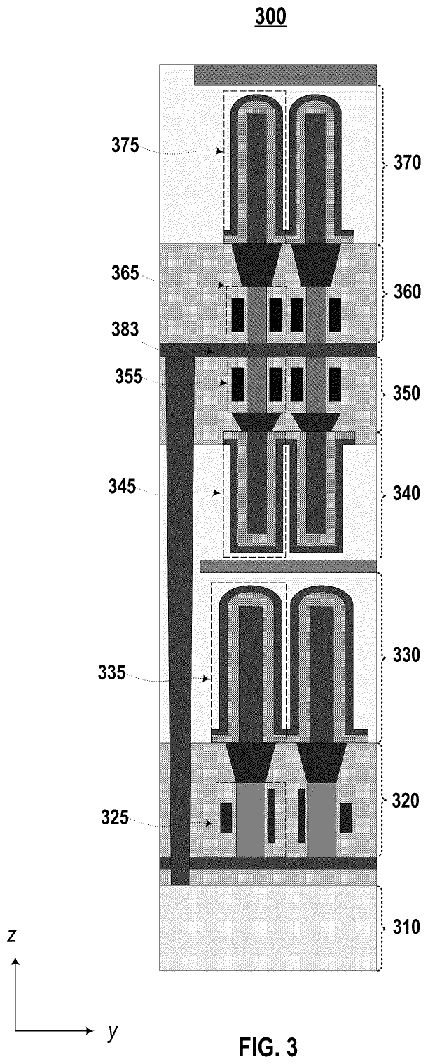

FIG. 3 illustrates a side view of a cross-section of a semiconductor device 300 including vertical transistors, according to some aspects of the present disclosure. It is understood that FIG. 3 is for illustrative purposes only and may not necessarily reflect the actual device structure (e.g., interconnections) in practice. Semiconductor device 300 can include a peripheral circuit layer 310 including the peripheral circuits of the semiconductor device 300. Semiconductor device 300 can also include a first semiconductor stack including a first transistor layer 320 and a first storage layer 330. Semiconductor device 200 can further include a second semiconductor stack including a second transistor layer 350 and a second storage layer 340. Semiconductor device 300 can further include a third semiconductor stack including a third transistor layer 360 and a third storage layer 370.

In some implementations, the peripheral circuit layer 310 can include any suitable peripheral circuits of the semiconductor device 300, and can be referred to as the peripheral circuit layer 210 of the semiconductor device 200 described above in connection with FIG. 2. In some implementations, the first transistor layer 320 can include an array of first transistors 325, and can be referred to as the first transistor layer 220 of the semiconductor device 200 described above in connection with FIG. 2. In some implementations, the first storage layer 330 can include an array of first capacitors 335, and can be referred to as the first storage layer 240 of the semiconductor device 200 described above in connection with FIG. 2. In some implementations, the second storage layer 340 can include an array of second capacitors 345, and can be referred to as the second storage layer 260 of the semiconductor device 200 described above in connection with FIG. 2. In some implementations, the second transistor layer 350 can include an array of second transistors 355, and can be referred to as the second transistor layer 280 of the semiconductor device 200 described above in connection with FIG. 2.

Different from the semiconductor device 200, the semiconductor device 300 further includes a third semiconductor stack including a third transistor layer 360 and a third storage layer 370. The third semiconductor stack is vertically stacked with the second semiconductor stack, the first semiconductor stack, and the peripheral circuit layer 310. The third transistor layer 360 can include an array of third transistors 365. In some implementations, the third transistors 365 can be the same type of transistors as the second transistors 355. The details of third transistors 365 can be referred to as the second transistors 290 in semiconductor device 200 described above in connection with FIG. 2. In some implementations, the third transistors 365 and the second transistors 355 can share a same set of bit lines 383. Therefore, the third transistor layer 360 and the second transistor layer 350 can be located between the third storage layer 370 and the second storage layer 340 in the vertical direction. The third storage layer 370 can include an array of third capacitors 375. In some implementations, the third capacitors 375 can be the same type of capacitors as the first capacitors 335. The details of third capacitors 375 can be referred to as the first capacitors 250 in semiconductor device 200 described above in connection with FIG. 2.

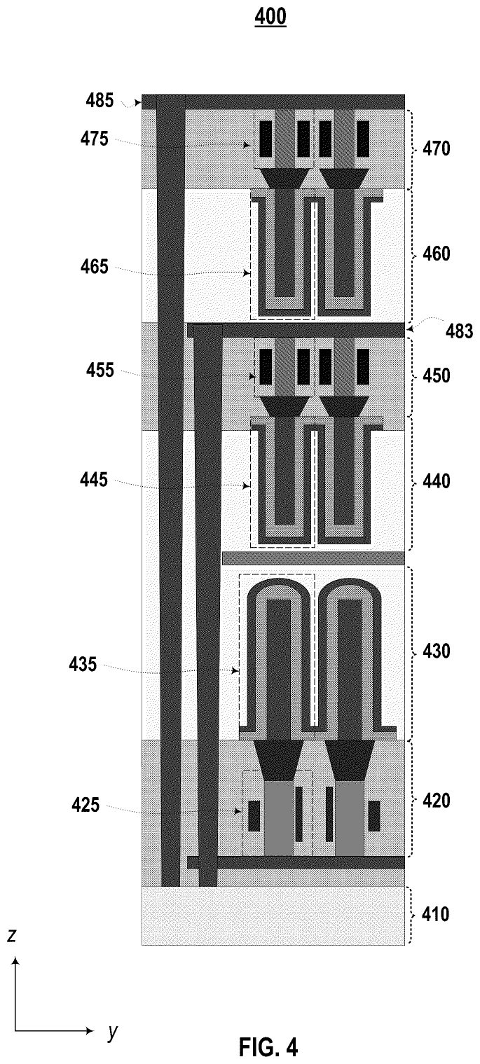

FIG. 4 illustrates a side view of a cross-section of a semiconductor device 400 including vertical transistors, according to some aspects of the present disclosure. It is understood that FIG. 4 is for illustrative purposes only and may not necessarily reflect the actual device structure (e.g., interconnections) in practice. Semiconductor device 400 can include a peripheral circuit layer 410 including the peripheral circuits of the semiconductor device 400. Semiconductor device 400 can also include a first semiconductor stack including a first transistor layer 420 and a first storage layer 430. Semiconductor device 400 can further include a second semiconductor stack including a second transistor layer 450 and a second storage layer 440. Semiconductor device 400 can further include a third semiconductor stack including a third transistor layer 470 and a third storage layer 460.

Similarly to semiconductor device 300, in some implementations, the peripheral circuit layer 410 of semiconductor device 400 can include any suitable peripheral circuits of the semiconductor device 400, and can be referred to as the peripheral circuit layer 210 of the semiconductor device 200 described above in connection with FIG. 2. In some implementations, the first transistor layer 420 can include an array of first transistors 425, and can be referred to as the first transistor layer 220 of the semiconductor device 200 described above in connection with FIG. 2. In some implementations, the first storage layer 430 can include an array of first capacitors 435, and can be referred to as the first storage layer 240 of the semiconductor device 200 described above in connection with FIG. 2. In some implementations, the second storage layer 440 can include an array of second capacitors 445, and can be referred to as the second storage layer 260 of the semiconductor device 200 described above in connection with FIG. 2. In some implementations, the second transistor layer 450 can include an array of second transistors 455, and can be referred to as the second transistor layer 280 of the semiconductor device 200 described above in connection with FIG. 2.

Compared with the semiconductor device 300, the third semiconductor stack including a third transistor layer 470 and a third storage layer 460 can be upset down. As shown in FIG. 4, the third semiconductor stack is vertically stacked with the second semiconductor stack, the first semiconductor stack, and the peripheral circuit layer 310. The third storage layer 460 can be located between the third transistor layer 470 and the second transistor layer 450 in the vertical direction. The second transistor layer 450 can be located between the second storage layer 440 and the third storage layer 460.

The third transistor layer 470 can include an array of third transistors 475. In some implementations, the third transistors 475 can be the same type of transistors as the second transistors 455. The details of third transistors 475 can be referred to as the second transistors 290 in semiconductor device 200 described above in connection with FIG. 2. In some implementations, the third transistors 475 and the second transistors 455 can be connected to different sets of bit lines 483 and 485, respectively. The third storage layer 460 can include an array of third capacitors 465. In some implementations, the third capacitors 465 can be the same type of capacitors as the second capacitors 445. The details of third capacitors 465 can be referred to as the second capacitors 270 in semiconductor device 200 described above in connection with FIG. 2.

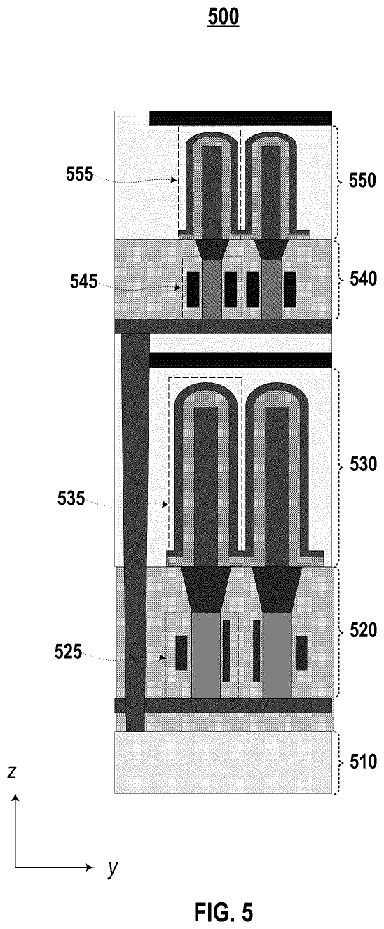

FIG. 5 illustrates a side view of a cross-section of a semiconductor device 500 including vertical transistors, according to some aspects of the present disclosure. It is understood that FIG. 5 is for illustrative purposes only and may not necessarily reflect the actual device structure (e.g., interconnections) in practice. Semiconductor device 500 can include a peripheral circuit layer 510 including the peripheral circuits of the semiconductor device 500. Semiconductor device 500 can also include a first semiconductor stack including a first transistor layer 520 and a first storage layer 530. Semiconductor device 500 can further include a second semiconductor stack including a second transistor layer 540 and a second storage layer 550.

Similarly to semiconductor device 200, in some implementations, the peripheral circuit layer 510 of semiconductor device 500 can include any suitable peripheral circuits of the semiconductor device 500, and can be referred to as the peripheral circuit layer 210 of the semiconductor device 200 described above in connection with FIG. 2. In some implementations, the first transistor layer 520 can include an array of first transistors 525, and can be referred to as the first transistor layer 220 of the semiconductor device 200 described above in connection with FIG. 2. In some implementations, the first storage layer 530 can include an array of first capacitors 535, and can be referred to as the first storage layer 240 of the semiconductor device 200 described above in connection with FIG. 2.

Different from the semiconductor device 200, the second semiconductor stack including a second transistor layer 540 and a second storage layer 550 can be upside down. The second semiconductor stack is vertically stacked with the first semiconductor stack and the peripheral circuit layer 310. The second transistor layer 540 can be located between the first storage layer 530 and the second storage layer 550 in the vertical direction. The second transistor layer 540 can include an array of second transistors 545. In some implementations, the second transistors 545 and the first transistors 525 can be different types of transistors. The details of second transistors 545 can be referred to as the second transistors 290 in semiconductor device 200 described above in connection with FIG. 2. The second storage layer 550 can include an array of second capacitors 555. In some implementations, the second capacitors 555 can be the same type of capacitors as the first capacitors 535. The details of second capacitors 555 can be referred to as the first capacitors 250 in semiconductor device 200 described above in connection with FIG. 2.

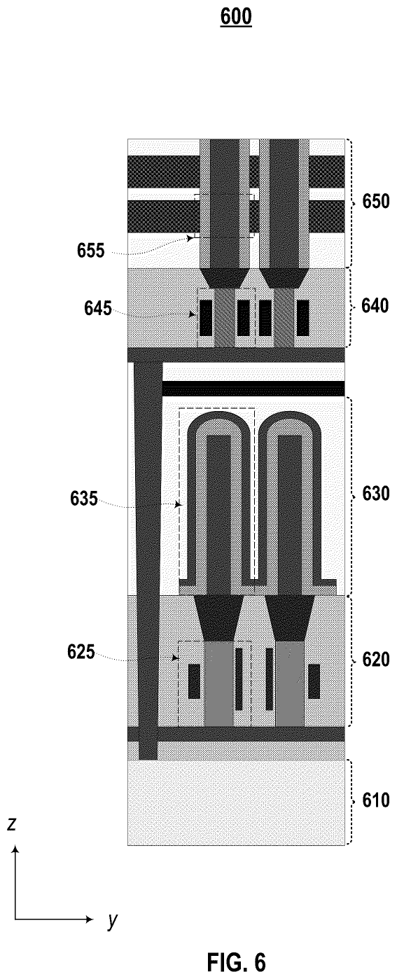

FIG. 6 illustrates a side view of a cross-section of a semiconductor device 600 including vertical transistors, according to some aspects of the present disclosure. It is understood that FIG. 6 is for illustrative purposes only and may not necessarily reflect the actual device structure (e.g., interconnections) in practice. Semiconductor device 600 can include a peripheral circuit layer 610 including the peripheral circuits of the semiconductor device 600. Semiconductor device 600 can also include a first semiconductor stack including a first transistor layer 620 and a first storage layer 630. Semiconductor device 600 can further include a second semiconductor stack including a second transistor layer 640 and a second storage layer 650.

Similarly to semiconductor device 500, in some implementations, the peripheral circuit layer 610 of semiconductor device 600 can include any suitable peripheral circuits of the semiconductor device 600, and can be referred to as the peripheral circuit layer 210 of the semiconductor device 200 described above in connection with FIG. 2. In some implementations, the first transistor layer 620 can include an array of first transistors 625, and can be referred to as the first transistor layer 220 of the semiconductor device 200 described above in connection with FIG. 2. In some implementations, the first storage layer 630 can include an array of first capacitors 635, and can be referred to as the first storage layer 240 of the semiconductor device 200 described above in connection with FIG. 2. The second transistor layer 640 can include an array of second transistors 645. In some implementations, the second transistors 645 and the first transistors 625 can be different types of transistors. The details of second transistors 645 can be referred to the second transistors 290 in semiconductor device 200 described above in connection with FIG. 2.

Different from the semiconductor device 500, the DRAM cells of the second deck including the second transistor layer 640 and the second storage layer 650 are 1TNC cells. That is, the second storage layer 650 can include multiple layers of second capacitors 655, each layer including an array of second capacitors 655. In some implementations, the second capacitors 655 and the first capacitors 635 can be different types of capacitors. For example, the first capacitors 635 can be traditional capacitors, with the capacitor dielectric layer being dielectric materials, such as silicon oxide, silicon nitride, or high-k dielectrics including, but not limited to, Al₂O₃, HfO₂, Ta₂O₅, ZrO₂, TiO₂, or any combination thereof. The second capacitors 655 are ferroelectric capacitors, with the capacitor dielectric layer being ferroelectric materials, such as PZT, BaTiO₃, SBT, PMN-PT, LiNbO₃, etc. The details of second capacitors 655 can be referred to the second capacitors 270 in semiconductor device 200 described above in connection with FIG. 2.

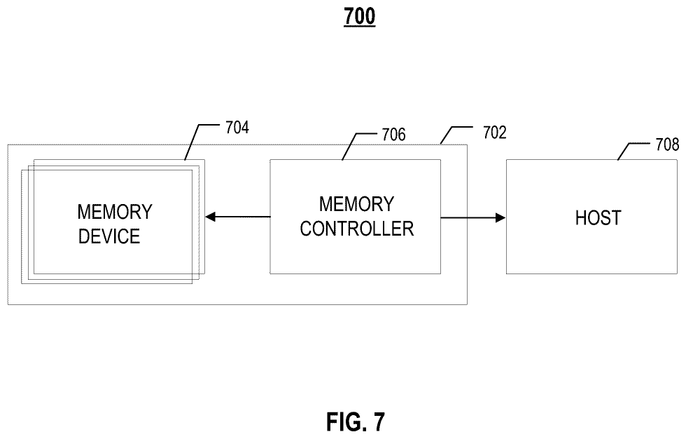

FIG. 7 illustrates a block diagram of a system 700 having a memory device, according to some implementations of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, system 700 can include a host 708 and a memory system 702 having one or more memory devices 704 and a memory controller 706. Host 708 can be a processor of an electronic device, such as a central processing unit (CPU), or a system-on-chip (SoC), such as an application processor (AP). Host 708 can be configured to send or receive the data to or from memory devices 704. Memory device 704 can be any memory device disclosed herein, such as semiconductor device 100. In some implementations, memory device 704 can include one or more of the semiconductor devices 200/300/400/500/600 shown in FIGS. 2-6, respectively, each including vertical transistors and vertical capacitors, as described above in detail.

Memory controller 706 is coupled to memory device 704 and host 708 and is configured to control memory device 704, according to some implementations. Memory controller 706 can manage the data stored in memory device 704 and communicate with host 708. Memory controller 706 can be configured to control operations of memory device 704, such as read, write, and refresh operations. Memory controller 706 can also be configured to manage various functions with respect to the data stored or to be stored in memory device 704 including, but not limited to refresh and timing control, command/request translation, buffer and schedule, and power management. In some implementations, memory controller 706 is further configured to determine the maximum memory capacity that the computer system can use, the number of memory banks, memory type and speed, memory particle data depth and data width, and other important parameters. Any other suitable functions may be performed by memory controller 706 as well. Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

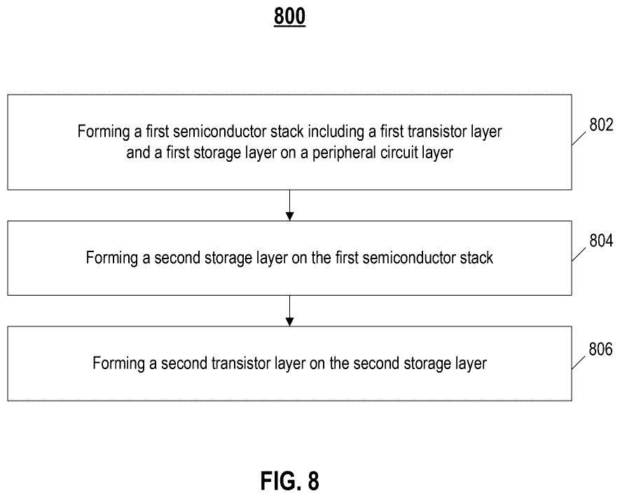

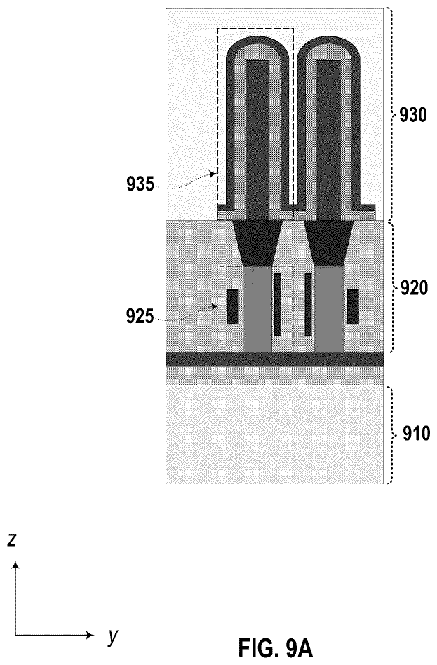

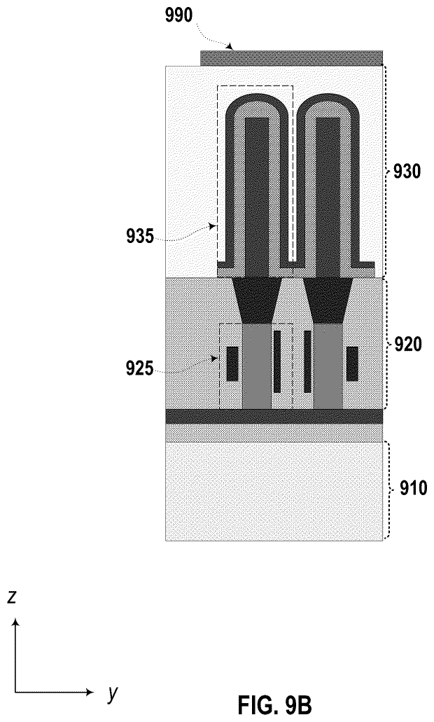

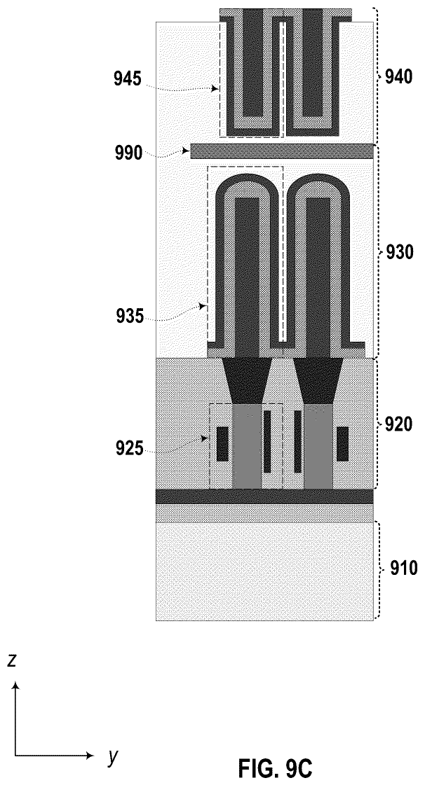

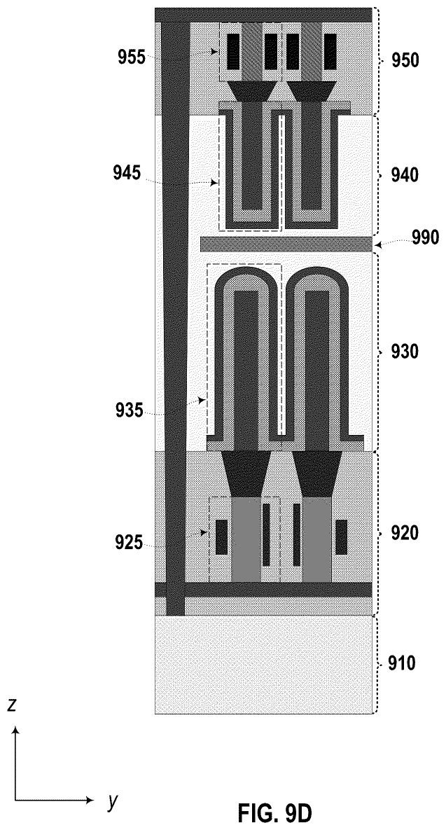

FIG. 8 illustrates a flowchart of a fabricating method 800 for forming a semiconductor device including DRAM cells, according to some implementations of the present disclosure. FIGS. 9A-9D illustrate schematic views of a semiconductor device at certain fabricating stages of the method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIG. 8, method 800 can start at operation 802, in which a first semiconductor stack including a first transistor layer and a first storage layer can be formed on a peripheral circuit layer. FIG. 9A illustrates a schematic side cross-sectional view of a semiconductor structure in the y-z plane after operation 802 of method 800. In some implementations, as shown in FIG. 9A, forming the first semiconductor stack can comprise forming a first transistor layer 920 comprising an array of first transistors 925 on the peripheral circuit layer 910. In some implementations, the peripheral circuit layer 910 can be formed to include any suitable peripheral circuits. In some implementations, forming the first semiconductor stack can further comprise forming a first storage layer 930 vertically stacked on the first transistor layer 920 and comprising an array of first capacitors 935 each coupled with a corresponding one of the array of the first transistors 925. In some implementations, forming the array of first transistors 925 comprises forming a first vertical channel structure for each first vertical transistor 925 by using a first material. In some implementations, forming the array of first transistors 925 further comprises forming a first gate structure of each first transistor 925 at a first number of sides of the first vertical channel structure.

In some implementations, the details of the fabricating processes of forming the semiconductor structure, including the first storage layer 930 and the first transistor layer 920, are disclosed in International Application No. PCT/CN2024/084121, filed on Mar. 27, 2024, entitled “SEMICONDUCTOR DEVICES AND FABRICATING METHODS THEREOF,” which is hereby incorporated by reference in its entirety.

Referring to FIG. 8, method 800 can proceed to operation 804, in which a second storage layer can be formed on the first semiconductor stack. FIGS. 9B-9C illustrate schematic side cross-sectional views of the semiconductor structure in the y-z plane at various stages of operation 804 of method 800. As shown in FIG. 9B, a separation layer 990 can be formed on the first storage layer 930. In some implementations, the separation layer 990 can be a heavily doped silicon layer, and can be formed by a series of fabricating processes, such as a deposition process or an epitaxial growth process, a doping process, a patterning process, etc. As shown in FIG. 9C, a second storage layer 940, including an array of second capacitors 945, can be formed on the separation layer 990. In some implementations, the second capacitors 945 are cup capacitors, and the detailed fabricating processes are disclosed, for example, in International Application No. PCT/CN2024/084113, filed on Mar. 27, 2024, entitled “SEMICONDUCTOR DEVICES AND FABRICATING METHODS THEREOF,” which is hereby incorporated by reference in its entirety.

Referring to FIG. 8, method 800 can proceed to operation 806, in which a second transistor layer can be formed on the second storage layer. FIG. 9D illustrates a schematic side cross-sectional view of the semiconductor structure in the y-z plane after operation 806 of method 800. As shown in FIG. 9D, a second transistors layer 950, comprising an array of second transistors 955, can be formed on the second storage layer 940. Each second transistor 955 can be coupled with a corresponding one of the array of second capacitors 945. In some implementations, forming the second transistors 955 can comprise forming a second vertical channel structure for each second vertical transistor by using a second material different from the first material. In some implementations, the first material is monocrystalline silicon, and the second material is polycrystalline silicon or silicon-germanium. In some other implementations, the first material is monocrystalline silicon, and the second material is a metal oxide semiconductor material. In some implementations, the metal oxide semiconductor material comprises one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O. In some implementations, forming the array of second transistors 955 further comprises forming a second gate structure of each second transistor 955 at a second number of sides of the second vertical channel structure, wherein the first number is different from the second number.

It is noted that, method 800 can further include any other suitable operations that are not shown in FIG. 8. For example, method 800 can further include forming first bit lines for the first transistors 925, and forming second bit lines for the second transistor 955. As another example, method 800 can further include forming one or more interconnection layers including forming a first bit line interconnection structure coupled between the peripheral circuits and first bit lines in the first semiconductor stack, and forming a second bit line interconnection structure extending through the first semiconductor stack and being coupled between the peripheral circuits and second bit lines in the second semiconductor stack. As yet another example, method 800 can further include forming SNCs connected between the transistors and the corresponding capacitors.

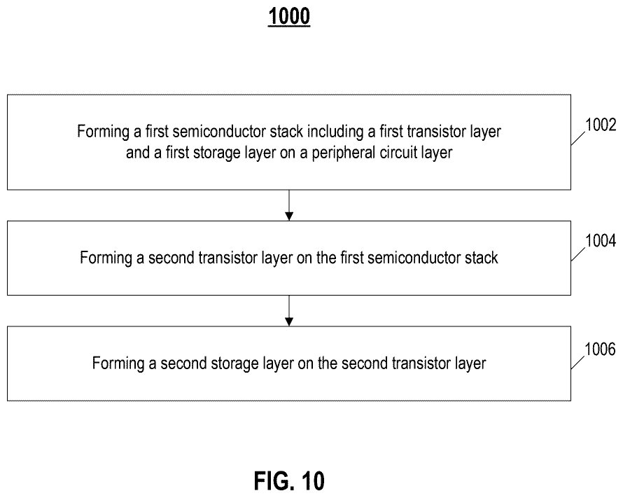

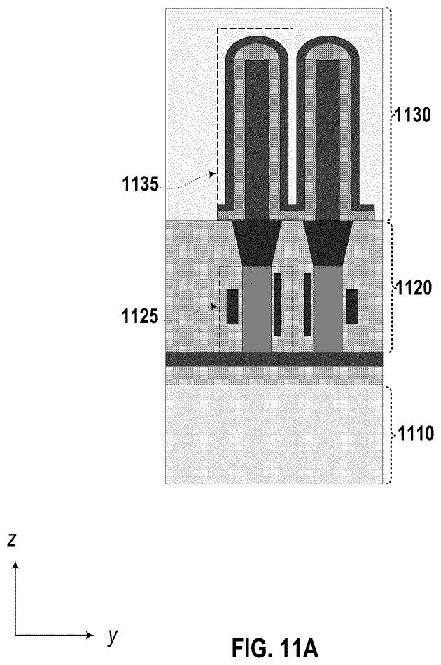

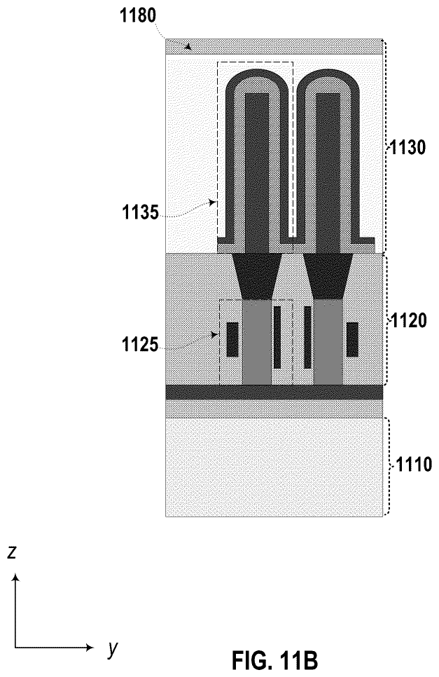

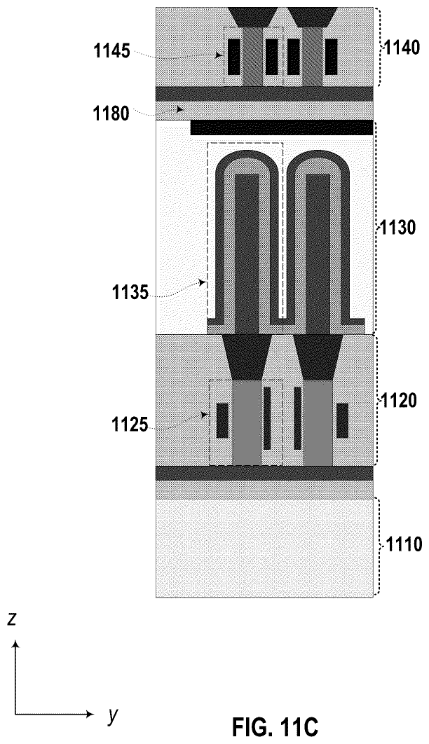

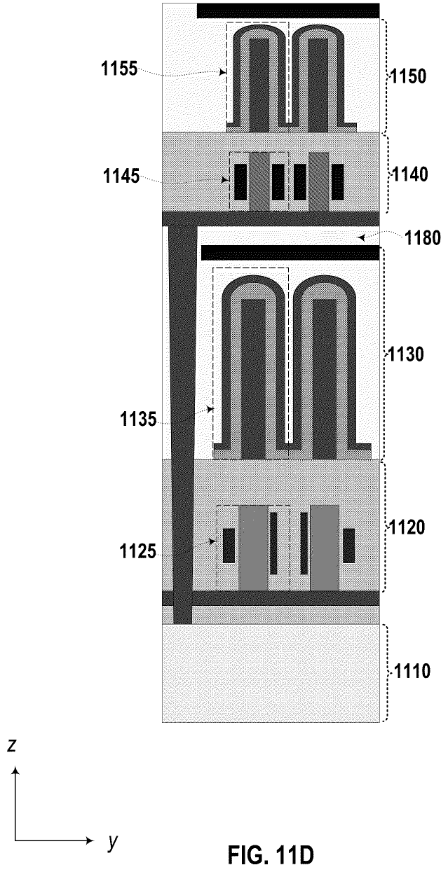

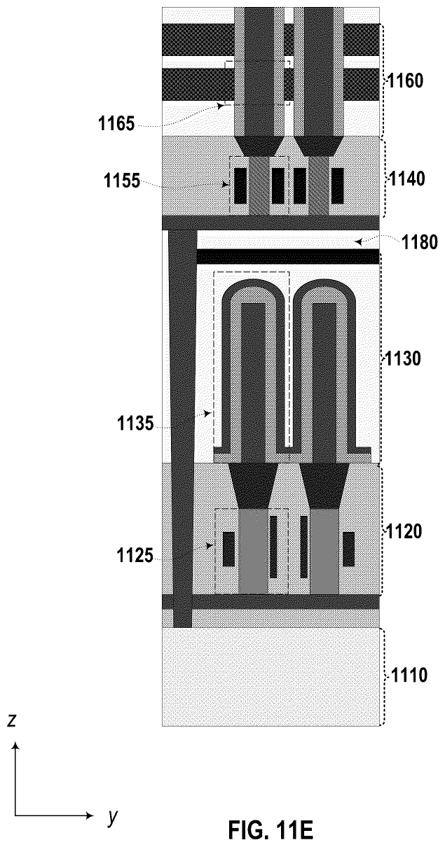

FIG. 10 illustrates a flowchart of a fabricating method 1000 for forming a semiconductor device including DRAM cells, according to some implementations of the present disclosure. FIGS. 11A-11E illustrate schematic views of a semiconductor device at certain fabricating stages of method 1000 shown in FIG. 10, according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIG. 10, method 1000 can start at operation 1002, in which a first semiconductor stack including a first transistor layer and a first storage layer can be formed on a peripheral circuit layer. FIG. 11A illustrates a schematic side cross-sectional view of a semiconductor structure in the y-z plane after operation 1002 of method 1000. In some implementations, as shown in FIG. 11A, forming the first semiconductor stack can comprise forming a first transistor layer 1120 comprising an array of first transistors 1125 on the peripheral circuit layer 1110. In some implementations, the peripheral circuit layer 1110 can be formed to include any suitable peripheral circuits. In some implementations, forming the first semiconductor stack can further comprise forming a first storage layer 1130 vertically stacked on the first transistor layer 1120 and comprising an array of first capacitors 1135 each coupled with a corresponding one of the array of the first transistors 1125. In some implementations, forming the array of first transistors 1125 comprises forming a first vertical channel structure for each first transistor 1125 by using a first material. In some implementations, forming the array of first transistors 1125 further comprises forming a first gate structure of each first transistor 1125 at a first number of sides of the first vertical channel structure.

Referring to FIG. 10, method 1000 can proceed to operation 1004, in which a second transistor layer can be formed on the first semiconductor stack. FIGS. 11B-11C illustrate schematic side cross-sectional views of the semiconductor structure in the y-z plane at various stages of operation 1004 of method 1000. As shown in FIG. 11B, a separation layer 1180 can be formed on first storage layer 1130. In some implementations, separation layer 1180 can be an oxide layer, and can be formed by a deposition process or an oxidation process, etc. As shown in FIG. 11C, a second transistor layer 1140, including an array of second transistors 1145, can be formed on the separation layer 1180. In some implementations, forming the second transistors 1145 can comprise forming a second vertical channel structure for each second vertical transistor by using a second material different from the first material. In some implementations, the first material comprises monocrystalline silicon, and the second material is polycrystalline silicon or silicon-germanium. In some other implementations, the first material is monocrystalline silicon, and the second material is a metal oxide semiconductor material. In some implementations, the metal oxide semiconductor material comprises one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O. In some implementations, forming the array of second transistors 1145 further comprises forming a second gate structure of each second transistor 1145 at a second number of sides of the second vertical channel structure, wherein the first number is different from the second number.

Referring to FIG. 10, method 1000 can proceed to operation 1006, in which a second storage layer can be formed on the second transistor layer. FIG. 11D and 11E each illustrates a schematic side cross-sectional view of a corresponding semiconductor structure in the y-z plane after operation 1006 of method 1000, according to various implementations. As shown in FIG. 11D, a second storage layer 1150/1160, comprising an array of second capacitors 1155/1165, can be formed on the second transistor layer 1140. Each second capacitor 1155/1165 can be coupled with a corresponding one of the array of second transistor 1145.

In some implementations, the DRAM cells including second transistor 1145 and corresponding second capacitor 1155 are 1T1C cells. In such implementations, second capacitors 1155 are cup capacitors, as shown in FIG. 11D, and their detailed fabricating processes can be referred to International Application No. PCT/CN2024/084121, filed on Mar. 27, 2024, entitled “SEMICONDUCTOR DEVICES AND FABRICATING METHODS THEREOF.” In some other implementations, each DRAM cell, including a second transistor 1145 and two or more corresponding second capacitors 1165, is a 1TNC cell. In such implementations, second capacitors 1155 can be ferroelectric capacitors, as shown in FIG. 11E.

It is noted that, method 1000 can further include any other suitable operations that are not shown in FIG. 10. For example, method 1000 can further include forming first bit lines for the first transistors 1125, and forming second bit lines for the second transistor 1145. As another example, method 1000 can further include forming one or more interconnection layers including forming a first bit line interconnection structure coupled between the peripheral circuits and first bit lines in the first semiconductor stack, and forming a second bit line interconnection structure extending through the first semiconductor stack and being coupled between the peripheral circuits and second bit lines in the second semiconductor stack. As yet another example, method 1000 can further include forming SNCs connected between the transistors and the corresponding capacitors.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A semiconductor device, comprising:
a first semiconductor stack comprising:
a first transistor layer comprising an array of first vertical transistors, each first vertical transistor comprising a first vertical channel structure comprising a first material, and
a first storage layer vertically stacked on the first transistor layer and comprising an array of first capacitors each coupled with a corresponding one of the array of the first vertical transistors; and
a second semiconductor stack being vertically stacked on the first semiconductor stack, and comprising:
a second transistor layer comprising an array of second vertical transistors, each second vertical transistor comprising a second vertical channel structure comprising a second material different from the first material, and
a second storage layer being vertically stacked on the second transistor layer and comprising an array of second capacitors each coupled with a corresponding one of the array of the second vertical transistors.

2. The semiconductor device of claim 1, wherein:
the first material is monocrystalline silicon; and
the second material is one of polycrystalline silicon, silicon-germanium, and a metal oxide semiconductor material.

3. The semiconductor device of claim 1, wherein:
each first vertical transistor further comprises a first gate structure located at a first number of sides of the first vertical channel structure;
each second vertical transistor further comprises a second gate structure located at a second number of sides of the second vertical channel structure; and
the first number is different from the second number.

4. The semiconductor device of claim 1, wherein:
each first capacitor comprises a high-K dielectric material between two conductive layers;
each second capacitor comprises a ferroelectric material between two conductive layers; and
the second storage layer comprises more than one layer of second capacitors.

5. The semiconductor device of claim 1, further comprising:
a peripheral circuit layer comprising peripheral circuits and being vertically stacked with the first semiconductor stack and the second semiconductor stack;
a first bit line interconnection structure coupled between the peripheral circuits and first bit lines in the first semiconductor stack; and
a second bit line interconnection structure extending through the first semiconductor stack and being coupled between the peripheral circuits and second bit lines in the second semiconductor stack.

6. The semiconductor device of claim 5, wherein:
the second transistor layer is located between the first storage layer and the second storage layer; and
the semiconductor device further comprises:
a first capacitor interconnection structure coupled between the peripheral circuits and a first common electrode of the first capacitors, and
a second capacitor interconnection structure extending through the first semiconductor stack and being coupled between the peripheral circuits and a second common electrode of the second capacitors.

7. The semiconductor device of claim 5, wherein:
the first storage layer and the second storage layer are located between the first transistor layer and the second transistor layer;
the array of first capacitors and the array of second capacitors share a common electrode; and
the semiconductor device further comprises a common capacitor interconnection structure extending in the first semiconductor stack and being coupled between the peripheral circuits and the common electrode.

8. The semiconductor device of claim 7, further comprising:
a third semiconductor stack being vertically stacked on the second semiconductor stack, and comprising:
a third transistor layer comprising an array of third vertical transistors, and
a third storage layer being vertically stacked on the third transistor layer and comprising an array of third capacitors each coupled with a corresponding one of the array of the third vertical transistors.

9. The semiconductor device of claim 8, wherein:
the second transistor layer and the third transistor layer are located between the second storage layer and the third storage layer; and
the array of second vertical transistors and the array of third vertical transistors share a common bit line layer.

10. The semiconductor device of claim 8, wherein:
the third storage layer is located between the second transistor layer and the third transistor layer; and
the semiconductor device further comprises a third bit line interconnection structure extending in the first, second, and third semiconductor stacks and being coupled between the peripheral circuits and third bit lines in the third semiconductor stack.

11. A semiconductor device, comprising:
a first semiconductor stack comprising:
a first transistor layer comprising an array of first vertical transistors, each first vertical transistor, and
a first storage layer vertically stacked on the first transistor layer and comprising an array of first capacitors each comprising a high-K dielectric material between two conductive layers and being coupled with a corresponding one of the array of the first vertical transistors; and
a second semiconductor stack being vertically stacked on the first semiconductor stack, and comprising:
a second transistor layer comprising an array of second vertical transistors, and
a second storage layer being vertically stacked on the second transistor layer and comprising an array of second capacitors each comprising a ferroelectric material between two conductive layers and being coupled with a corresponding one of the array of the second vertical transistors.

12. The semiconductor device of claim 11, wherein:
the second storage layer comprises more than one layer of second capacitors.

13. The semiconductor device of claim 11, wherein:
each first vertical transistor comprising a first vertical channel structure comprising a first material; and
each second vertical transistor comprising a second vertical channel structure comprising a second material different from the first material.

14. The semiconductor device of claim 13, wherein:
the first material is monocrystalline silicon; and
the second material is one of polycrystalline silicon, silicon-germanium, and a metal oxide semiconductor material.

15. The semiconductor device of claim 13, wherein:
each first vertical transistor further comprises a first gate structure located at a first number of sides of the first vertical channel structure;
each second vertical transistor further comprises a second gate structure located at a second number of sides of the second vertical channel structure; and
the first number is different from the second number.

16. The semiconductor device of claim 11, further comprising:
a peripheral circuit layer comprising peripheral circuits and being vertically stacked with the first semiconductor stack and the second semiconductor stack;
a first bit line interconnection structure coupled between the peripheral circuits and first bit lines in the first semiconductor stack; and
a second bit line interconnection structure extending through the first semiconductor stack and being coupled between the peripheral circuits and second bit lines in the second semiconductor stack.

17. The semiconductor device of claim 16, wherein:
the second transistor layer is located between the first storage layer and the second storage layer; and
the semiconductor device further comprises:
a first capacitor interconnection structure coupled between the peripheral circuits and a first common electrode of the first capacitors, and
a second capacitor interconnection structure extending through the first semiconductor stack and being coupled between the peripheral circuits and a second common electrode of the second capacitors.

18. The semiconductor device of claim 16, wherein:
the first storage layer and the second storage layer are located between the first transistor layer and the second transistor layer;
the array of first capacitors and the array of second capacitors share a common electrode; and
the semiconductor device further comprises a common capacitor interconnection structure extending in the first semiconductor stack and being coupled between the peripheral circuits and the common electrode.

19. The semiconductor device of claim 18, further comprising:
a third semiconductor stack being vertically stacked on the second semiconductor stack, and comprising:
a third transistor layer comprising an array of third vertical transistors, and
a third storage layer being vertically stacked on the third transistor layer and comprising an array of third capacitors each coupled with a corresponding one of the array of the third vertical transistors.

20. A method for forming a semiconductor device, comprising:
forming a first semiconductor stack comprising:
forming a first transistor layer comprising an array of first vertical transistors, comprising forming a first vertical channel structure for each first vertical transistor having a first material, and
forming a first storage layer vertically stacked on the first transistor layer and comprising an array of first capacitors each coupled with a corresponding one of the array of the first vertical transistors; and
forming a second semiconductor stack vertically stacked on the first semiconductor stack, and comprising:
forming a second transistor layer comprising an array of second vertical transistors, comprising forming a second vertical channel structure for each second vertical transistor having a second material different from the first material, and
forming a second storage layer being vertically stacked on the second transistor layer and comprising an array of second capacitors each coupled with a corresponding one of the array of the second vertical transistors.
